(19) United States
(12) Patent Application Publication
(10) Pub. No.: US 2026/0245608 A1
(43) Pub. Date: Aug. 20, 2026

(54) COUPLING CONDUCTIVE LINES OF A MEMORY DEVICE DURING SELF-REFRESH

(71) Applicant: Micron Technology, Inc., Boise, ID (US)

(72) Inventors: Wonjun Choi, Boise, ID (US); Hyun Yoo Lee, Boise, ID (US)

(73) Assignee: Micron Technology, Inc., Boise, ID (US)

(21) Appl. No.: 19/271,233

(22) Filed: Jul. 16, 2025

Related U.S. Application Data
(60) Provisional application No. 63/677,932, filed on Jul. 31, 2024.

(51) Int. Cl. G11C 11/406; G11C 11/4074

(52) U.S. Cl. CPC G11C 11/40615; G11C 11/40626; G11C 11/4074

(57) ABSTRACT

Apparatuses, systems, and methods for self-refresh in a memory device are disclosed. The memory device receives a plurality of voltages at respective conductive lines of a plurality of conductive lines of the memory device. During at least a portion of a self-refresh mode, the memory device may conductively couple first and second conductive lines of the plurality of conductive lines. For example, the memory device may conductively couple a first conductive line that receives VDD and a second conductive line that receives VDDQ. The voltages may be received via respective rails of a power management integrated circuit (PMIC).

### BACKGROUND

This disclosure relates generally to semiconductor devices, and more specifically to semiconductor memory devices. For example, disclosed embodiments may relate to volatile memory, such as dynamic random-access memory (DRAM). Information may be stored on individual memory cells of the memory device as a physical signal (e.g., a charge on a capacitive element). During a read operation, the physical signal (e.g., the charge) may be coupled to a conductive element to cause a change in voltage. That change in voltage may be amplified and read out to input/output terminals of the device. A write operation may reverse the process, receiving a signal at the terminals and providing a voltage to the memory cell (e.g., to charge the capacitor).

Various types of memory devices exist, including random access memory (RAM), read only memory (ROM), dynamic RAM (DRAM), synchronous dynamic RAM (SDRAM), ferroelectric RAM (FeRAM), magnetic RAM (MRAM), resistive RAM (RRAM), flash memory, phase change memory (PCM), and others. Memory devices may be volatile or non-volatile. Non-volatile memory, e.g., FeRAM, may maintain their stored logic state for extended periods of time even in the absence of an external power source. Volatile memory devices, e.g., DRAM, may lose their stored state when disconnected from an external power source.

In some cases, a memory device may perform refresh operations to read and restore the state of volatile memory cells to mitigate the potential loss of state information. For example, some volatile memory cells, such as DRAM cells, include a capacitor for storing the state of the memory cell, and such memory cells may need to be periodically refreshed.

### BRIEF DESCRIPTION OF THE DRAWINGS

FIG. 1 is a block diagram of a memory device according to an embodiment of the disclosure.

FIG. 2 is a timing diagram illustrating self-refresh operations performed by a memory device.

FIG. 3 is a timing diagram illustrating self-refresh operations performed by a memory device at a high temperature.

FIG. 4 is a circuit diagram illustrating a switch according to an embodiment of the disclosure.

FIG. 5 is a block diagram illustrating a refresh control circuit of a memory device.

FIG. 6 is a timing diagram illustrating self-refresh operations performed by a memory device.

### DETAILED DESCRIPTION

The following description of certain embodiments is merely illustrative in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Information in a memory device is stored memory cells of a memory array. The information is conveyed as voltages along various internal signal lines. For example, a first voltage may represent a logical high, while a second voltage may represent a logical low. Memory devices may perform refresh operations to prevent loss of the information. For example, memory cells may be refreshed by reading and restoring (e.g., restoring back to a first stored level) the state of the memory cells to mitigate the potential loss of state information due to, for example, charge leakage. For example, DRAM cells may include a capacitor for storing the state of the memory cell, and such memory cells may need to be refreshed to compensate for charge leakage from the capacitor over time. One or more refresh operations may be performed in response to receiving a refresh command from, for example, a controller or a host device, such as an auto-refresh command. Additionally, refresh operations may be performed in a self-refresh mode based on internal logic of a memory device in response to a self-refresh entry command.

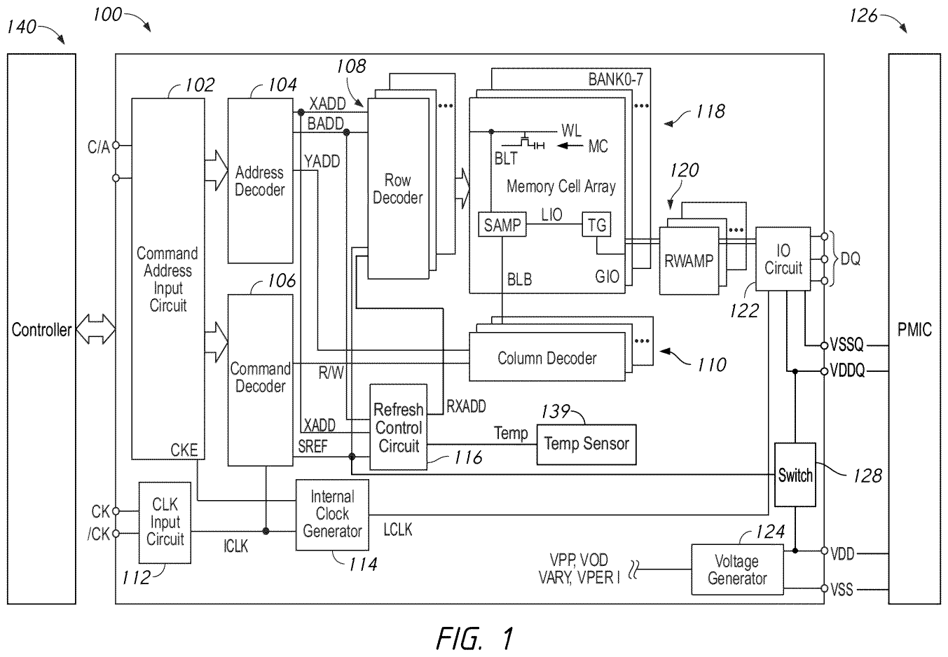

FIG. 1 is a block diagram of a memory device 100 according to an embodiment of the disclosure. The memory device 100 may be, for example, a DRAM device integrated on a single semiconductor chip. The memory device 100 is coupled to a controller 140 and a power management circuit 126 (e.g., a power management integrated circuit (PMIC)). The controller 140 accesses the memory device 100 by passing commands and addresses along command and address (C/A) terminals and sends and receives data to/from the memory device along external data terminals (DQ). Additionally, the controller 140 provides one or more chip select (CS) signals along CS terminals. The power management circuit 126 provides voltages (e.g., VSSQ, VDDQ, VDD, VSS) to the memory device 100 (e.g., via respective rails of the power management circuit 126

The memory device 100 includes a memory array 118. The memory array 118 is shown as including a plurality of memory banks. In the embodiment of FIG. 1, the memory array 118 is shown as including eight memory banks BANK0-BANK7. More or fewer banks can be included in the memory array 118 of other embodiments. Each memory bank includes a plurality of word lines WL, a plurality of bit lines BLT and BLB, and a plurality of memory cells MC arranged at intersections of the plurality of word lines WL and the plurality of bit lines BLT (and BLB). The selection of the word line WL is performed by a row decoder 108 and the selection of the bit lines BLT, BLB is performed by a column decoder 110. In the embodiment of FIG. 1, the row decoder 108 includes a respective row decoder for each memory bank and the column decoder 110 includes a respective column decoder for each memory bank. The bit lines BLT, BLB are coupled to a respective sense amplifier (SAMP). Read data from the bit line BLT (or BLB) is amplified by the sense amplifier SAMP and transferred to read/write amplifiers 120 over local data lines (LIO), transfer gate (TG), and global data lines (GIO). Conversely, write data outputted from the read/write amplifiers 120 is transferred to the sense amplifier SAMP over the complementary main data lines GIO, the transfer gate TG, and the complementary local data lines LIO, and written in the memory cell MC coupled to the bit line BLT (or BLB).

The memory device 100 may employ a plurality of external terminals that include command and address (C/A) terminals coupled to a command and address bus to receive commands and addresses from the controller 140, clock terminals to receive clocks CK and/CK from the controller 140, data terminals DQ coupled to a data bus to provide data to the controller 140, and power supply terminals to receive power supply potentials VDD, VSS, VDDQ, and VSSQ from the power management circuit 126 at respective conductive lines of the memory device 100.

The clock terminals are supplied with external clocks CK and/CK by the controller 140 that are provided to an input circuit 112. The external clocks may be complementary. The input circuit 112 generates an internal clock ICLK based on the CK and/CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. For example, the internal data clocks LCLK are provided to the input/output circuit 122 to time operation of circuits included in the input/output circuit 122, for example, to data receivers to time the receipt of write data. The input/output circuit 122 may include a number of interface connections, each of which may be couplable to one of the DQ pads (e.g., the solder pads which may function as external connections to the memory device 100).

The C/A terminals may be supplied with memory addresses by the controller 140. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The column decoder 110 may provide a column select signal, which may select one or more of the sense amplifiers SAMP. The address decoder 104 may also supply a decoded bank address BADD, which may indicate the bank of the memory array 118 containing the decoded row address XADD and column address YADD. The C/A terminals may be supplied with commands by the controller 140. Examples of commands include refresh commands (e.g., auto-refresh commands), self-refresh commands (e.g., self-refresh entry commands, self-refresh exit commands), activate commands for activating pages of memory, access commands for accessing the memory, such as read commands for performing read operations and write commands for performing write operations, as well as other commands and operations. The activate and access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line.

The memory device 100 may receive an access command from the controller 140 which is a read command. When activate and read commands are received, and a bank address, a row address, and a column address are timely supplied with the activate and read commands, read data is read from memory cells in the memory array 118 corresponding to the row address and column address. The read command is received by the command decoder 106, which provides internal commands so that read data from the memory array 118 is provided to the read/write amplifiers 120. The read data is provided along the data bus and output to outside from the data terminals DQ via the input/output circuit 122.

The memory device 100 may receive an access command from the controller 140 which is a write command. When activate and write commands are received, and a bank address, a row address, and a column address are timely supplied with the activate and write commands, write data supplied to the data terminals DQ is provided along the data bus and written to a memory cells in the memory array 118 corresponding to the row address and column address. The write command is received by the command decoder 106, which provides internal commands so that the write data is received by data receivers in the input/output circuit 122. Write clocks may also be provided to the external clock terminals for timing the receipt of the write data by the data receivers of the input/output circuit 122. The write data is supplied via the input/output circuit 122 to the read/write amplifiers 120, and by the read/write amplifiers 120 to the memory array 118 to be written into the memory cell MC.

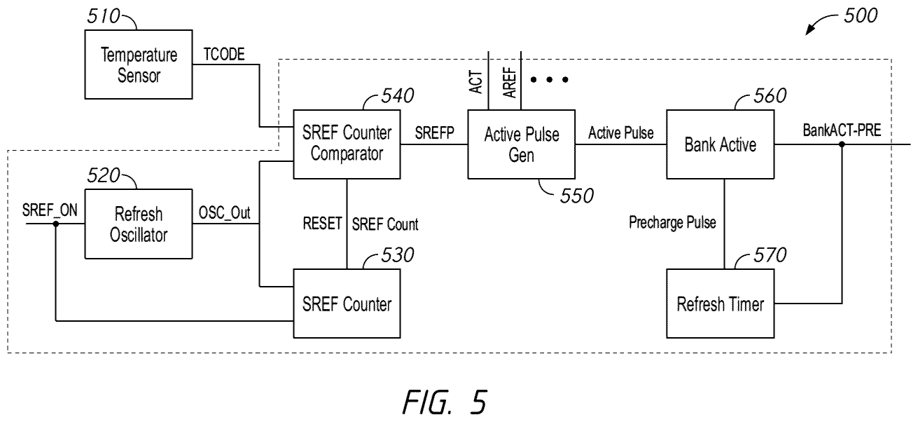

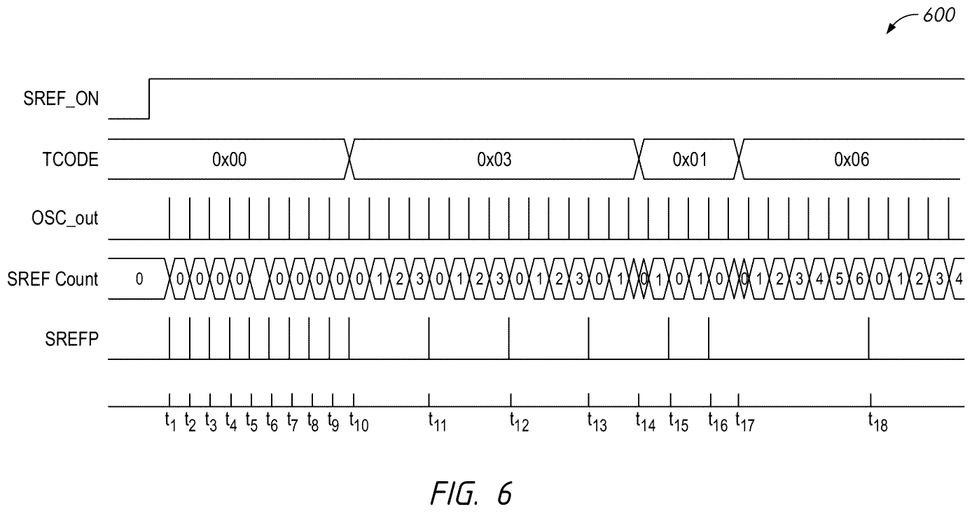

The memory device 100 may receive commands causing it to carry out one or more refresh operations, such as a self-refresh entry command to cause performance of self-refresh operations as part of a self-refresh mode. When an external signal indicates a self-refresh entry command, the command decoder 106 may decode the self-refresh entry command and provide the refresh signal SREF. The refresh signal SREF is supplied to the refresh control circuit 116. The refresh control circuit 116 supplies a refresh row address RXADD to the row decoder 108, which may refresh one or more word lines WL indicated by the refresh row address RXADD. The refresh control circuit 116 may control a timing of the refresh operation and may generate and provide the refresh address RXADD. In various embodiments, the refresh control circuit 116 causes performance of refresh operations based on a temperature signal TEMP provided by the temperature sensor 139. For example, the refresh control circuit may cause performance of refresh operations according to a self-refresh rate based on the temperature signal TEMP, as described with reference to FIGS. 5 and 6.

Power supply terminals of the memory device 100 are supplied with power supply potentials VDD and VSS by the power management circuit 126. The power supply potentials VDD and VSS are supplied to an internal voltage generator circuit 124. The internal voltage generator circuit 124 generates various internal potentials VPP, VOD, VARY, VPERI, and the like based on the power supply potentials VDD and VSS supplied to the power supply terminals. The power supply terminals are also supplied with power supply potential VDDQ by the power management circuit 126. The power supply potentials VDDQ and VSS are supplied to the input/output circuit 122. The power supply potential VDDQ supplied to the power supply terminals may be the same potentials as the power supply potential VDD supplied to the power supply terminals in an embodiment of the disclosure. The power supply potential VDDQ supplied to the power supply terminals may be a different potential from the power supply potential VDD supplied to the power supply terminals in another embodiment of the disclosure. The power supply potential VDD supplied to the power supply terminals are used for the input/output circuit 122 so that power supply noise generated by the input/output circuit 122 does not propagate to the other circuit blocks.

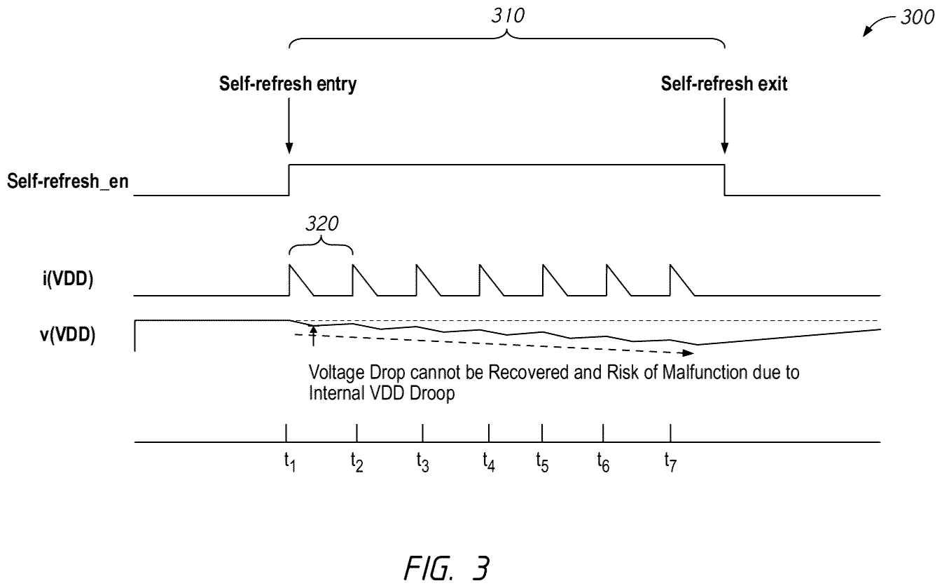

In embodiments of the disclosure, a switch 128 is activated to provide a conductive path between conductive lines of the memory device 100, such as a first conductive line at which power supply potential VDD is received from the power management circuit 126 and a second conductive line at which power supply potential VDDQ is received from the power management circuit 126, when the memory device 100 is in a self-refresh mode. In various embodiments, functionalities of the input/output circuit 122 may be unused or disabled during the self-refresh mode because, for example, no data is received or provided at the data terminals DQ during the self-refresh mode. Accordingly, the switch 128 can be activated during at least a portion of the self-refresh mode to conductively couple the first conductive line at which power supply potential VDD is received and the second conductive line at which power supply potential VDDQ is received, such that power from a plurality of rails of the power management circuit 126 can be used to increase the amount of current available for performance of self-refresh operations and help to prevent irrecoverable drops in voltage due to frequent self-refresh operations, as described with reference to FIG. 3. For example, activating the switch 128 allows power from a plurality of rails of the power management circuit 126 to be provided to the voltage generator 124, which provides the power that is used by the memory arrays 118 to refresh the memory cells MC. While example embodiments may provide a conductive path between conductive lines of the memory 100, the disclosed technology can be implemented in other ways. For example, the conductive path may alternatively be provided at pads or terminals of the memory 100 or external to the memory (e.g., at the power management circuit 126). Additionally, while examples are provided related to coupling conductive lines for VDD and VDDQ, other voltages may additionally or alternatively be coupled, and more voltages may be coupled (e.g., three or more voltages) in various embodiments.

The controller 140 may issue a self-refresh entry command, and the command decoder 106 may decode the self-refresh entry command and provide the refresh signal SREF to the refresh control circuit 116, which causes the memory device 100 to perform self-refresh operations. The refresh signal SREF may also be provided to the switch 128 to activate the switch 128 to provide the conductive path between the conductive lines. In an example implementation, the switch is activated during the self-refresh mode to conductively couple a conductive line at which VDD is received and a conductive line at which VDDQ is received, each conductive line being coupled to a respective rail of the power management circuit 126, thereby increasing the amount of power available for performance of self-refresh operations when the memory device 100 is in the self-refresh mode. For example, increased power can be supplied to the voltage generator 124, which provides power for performance of refresh operations by the memory array 118 to refresh memory cells MC. The switch 128 may be deactivated when the memory device 100 exits the self-refresh mode. For example, the memory device 100 may exit the self-refresh mode responsive to a self-refresh exit command. As used herein, a self-refresh exit command can refer to a sequence of events that, when performed, cause a memory to exit a self-refresh mode. For example, self-refresh exit can be triggered when a chip select signal (e.g., CS_n) transitions from low to high and stays high for at least a threshold time (e.g., tCSH_SRExit), when a CA bus is driven high at least a threshold time (e.g., tCASRX) prior to the chip select signal transitioning high, and when three no-operation (NOP) commands are received. The self-refresh exit command can also require that one or more timing delay criteria must be satisfied.

In various embodiments, the switch 128 is activated during a portion of the self-refresh mode, such as when a self-refresh interval for a self-refresh operation is below a threshold value, when a voltage (e.g., VDD) falls below a threshold value, or when a temperature of the memory device 100 exceeds a threshold value.

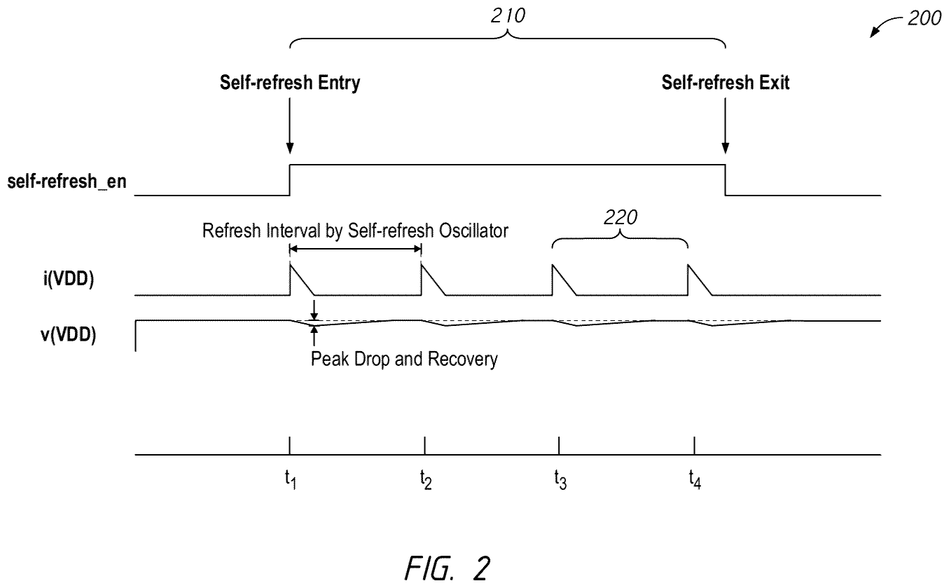

FIG. 2 is a timing diagram 200 illustrating self-refresh operations performed by a memory device. At a time t₁, a refresh signal self-refresh_en is provided at an active level responsive to a memory device receiving a self-refresh entry command from a controller, which causes the memory device to enter a self-refresh mode 210. For example, the refresh signal self-refresh_en may be provided by a command decoder of the memory device responsive to the self-refresh entry command.

During the self-refresh mode 210, the memory device performs self-refresh operations based on internal logic of a refresh control circuit of the memory device. The self-refresh operations are performed at an interval 220 determined using a temperature sensor and components of the refresh control circuit, such as a self-refresh oscillator, a self-refresh counter, and a self-refresh counter comparator, as described with reference to FIGS. 5 and 6. For example, a first self-refresh operation is performed at time t₁, a second refresh operation is performed at a time t₂, a third refresh operation is performed at a time t₃, and a fourth refresh operation is performed at a time t₄. The interval 220 between successive self-refresh operations may be determined by the refresh control circuit based on a temperature of the memory device. During performance of the self-refresh operations, a current i(VDD) increases, which causes a voltage v (VDD) to temporarily drop. For example, the voltage v (VDD) may be supplied by a single rail of a power source, which may provide limited power. In the example of FIG. 2, the memory device operates normally such that the voltage v (VDD) may recover and return to its normal level before performance of a next self-refresh operation. However, if the interval 220 is decreased (e.g., due to an increase in the temperature of the memory device), the single power rail of the power source may be insufficient to provide the current i(VDD) and the voltage v (VDD), and the voltage v (VDD) may be unable to return to its normal level, as described with reference to FIG. 3.

FIG. 3 is a timing diagram 300 illustrating self-refresh operations performed by a memory device at a high temperature. At a time t₁, a refresh signal self-refresh_en is provided at an active level responsive to a memory device receiving a self-refresh entry command from a controller, which causes the memory device to enter a self-refresh mode 310. For example, the refresh signal self-refresh_en may be provided by a command decoder of the memory device responsive to the self-refresh entry command.

During the self-refresh mode 310, the memory device performs self-refresh operations based on internal logic of a refresh control circuit of the memory device. The self-refresh operations are performed at an interval 320 determined using a temperature sensor and components of the refresh control circuit, such as a self-refresh oscillator, a self-refresh counter, and a self-refresh counter comparator, as described with reference to FIGS. 5 and 6. For example, a first self-refresh operation is performed at time t₁, a second refresh operation is performed at a time t₂, a third refresh operation is performed at a time t₃, a fourth refresh operation is performed at a time t₄, a fifth refresh operation is performed at a time t₅, a sixth refresh operation is performed at a time to, and a seventh refresh operation is performed at a time t₇. The interval 320 between successive refresh operations may be determined by the refresh control circuit based on a temperature of the memory device. As compared to the interval 220 of FIG. 2, the interval 320 is shorter, for example, due to a higher temperature of the memory device. That is, the refresh control circuit may cause more frequent self-refresh operations as the temperature of the memory device increases. During performance of the self-refresh operations, a current i (VDD) increases, which causes a voltage v (VDD) to drop. For example, the voltage v (VDD) may be supplied by a single rail of a power source, which may provide limited power. In the example of FIG. 3, the interval 320 is too short for the voltage v (VDD) to recover to a normal level before another self-refresh operation is performed. As a result, voltage v (VDD) may fall below a recoverable level, and the memory device is at an increased risk of malfunctioning because sufficient power cannot be supplied to perform the self-refresh operations.

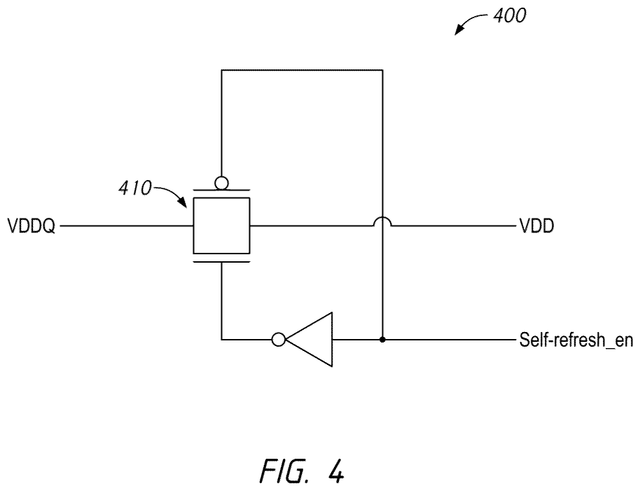

To address this problem, the disclosed technology increases the amount of power available for performance of the self-refresh operations by activating a switch to provide a conductive path between two or more power rails of a power management device. For example, the switch 128 of FIG. 1 and/or the switch 410 of FIG. 4 is activated to conductively couple voltages VDD and VDDQ during at least a portion of a self-refresh mode, thereby increasing the amount of power available for self-refresh operations and reducing the risk of malfunctioning due to insufficient power for performance of self-refresh operations, as illustrated with reference to FIG. 3. The disclosed technology may provide increased power to a voltage generator of a memory device, which provides power for performance of refresh operations on memory cells in a memory array.

FIG. 4 is a circuit diagram 400 illustrating a switch 410 according to an embodiment of the disclosure. For example, the switch 410 may be the switch 128 of FIG. 1. The switch 128 is coupled to a first conductive line of a memory device that receives a first voltage VDD and a second conductive line of the memory device that receives a second voltage VDDQ. The first conductive line is coupled to a first rail of a power management circuit via which the first voltage VDD is received, and the second conductive line is coupled to a second rail of the power management circuit via which the second voltage VDDQ is received.

A refresh signal self-refresh_en (e.g., SREF of FIG. 1) is received by the switch 410 when the memory device is in a self-refresh mode. For example, the memory device receives a self-refresh command from a controller. The self-refresh command is decoded by a command decoder of the memory device, and the command decoder provides the refresh signal self-refresh_en to the switch 410 at an active level. Responsive to the refresh signal self-refresh_en, the switch 410 is activated to provide a conductive path between the first conductive line and the second conductive line, thereby allowing the memory device to use voltage via both the first rail and the second rail of the power management circuit during the self-refresh mode. As a result, increased power can be provided to a voltage generator of the memory device, which provides power for performance of refresh operations to refresh memory cells in a memory array.

When the memory device exits the self-refresh mode, the refresh signal self-refresh_en is no longer provided at the active level, and the switch 410 is deactivated to conductively decouple the first conductive line and the second conductive line.

Advantageously, the disclosed technology allows coupling of the first and second conductive lines when VDDQ is not otherwise being used (e.g., to provide input/output functionality of the memory device) because the memory is in the self-refresh mode. As a result, multiple power rails of a power management circuit (or other power source) may be used to provide power needed to perform self-refresh operations, thereby reducing the risk of a malfunction, as illustrated with reference to FIG. 3. Because multiple power rails may be used to provide power for the self-refresh operations, the voltage (e.g., v (VDD) of FIG. 3) may recover more quickly following self-refresh operations, thereby allowing self-refresh operations to be performed at an increased rate without causing an irrecoverable drop in voltage.

In various embodiments, the switch 410 is activated during a portion of the self-refresh mode. In various embodiments, the first voltage VDD and the second voltage VDDQ may be equal.

FIG. 5 is a block diagram illustrating a refresh control circuit 500 of a memory device. For example, the refresh control circuit 500 can be the refresh control circuit 116 of the memory device 100 of FIG. 1. The refresh control circuit 500 causes performance of refresh operations by the memory device, such as auto-refresh operations and self-refresh operations. For example, the memory device enters a self-refresh mode and performs self-refresh operations responsive to receiving a self-refresh activation signal SREF_ON (e.g., SREF of FIG. 1). In an example implementation, the memory device receives a self-refresh command from a memory controller (e.g., 140 of FIG. 1), and the self-refresh command is decoded by a command decoder (e.g., 106 of FIG. 1), which generates the self-refresh activation signal SREF_ON and provides the self-refresh activation signal SREF_ON to the refresh control circuit 500.

A refresh oscillator 520 generates an oscillator signal OSC_out at an interval. For example, the refresh oscillator 520 may be activated by the self-refresh activation signal SREF_ON to generate the oscillator signal OSC_out as a pulse during a regular interval when the memory is in the self-refresh mode. The interval for the oscillator signal OSC_out may be, for example, 0.5 microseconds.

The refresh control circuit further includes a self-refresh counter 530 that receives the oscillator signal OSC_out from the refresh oscillator and maintains a count of pulses of the oscillator signal OSC_out (e.g., since a most recent self-refresh operation or a change in the temperature signal TCODE). The self-refresh counter 530 generates a self-refresh count signal SREF count indicating the count. The count maintained by the self-refresh counter 530 may be reset responsive to performance of a refresh operation or an updated temperature signal TCODE provided by a temperature sensor 510.

The refresh control circuit 500 is coupled to the temperature sensor 510 (e.g., 139 of FIG. 1), which determines a current temperature of the memory device and generates the temperature signal TCODE based on the current temperature. The temperature signal TCODE is used to control timing of refresh operations. For example, the temperature signal TCODE may cause self-refresh operations to be performed with greater frequency as temperature of the memory device increases. In various implementations, a value of the temperature signal TCODE indicates a value of the self-refresh count signal SREF count that triggers a refresh operation, such that lower values of the temperature signal TCODE (e.g., 0x00) correspond to more frequent self-refresh operations and higher values (e.g., 0x07) correspond to less frequent self-refresh operations. Example temperature signals TCODE and corresponding temperature information are illustrated in Table 1 below.

TABLE 1

| | Temperature | |
|---|---|---|
| Temperature | Signal (TCODE) | Self-Refresh Interval |
| First Range (lower | 0x07 | When SREF count = 7 (e.g., |
| temperature) | | after 8 pulses of oscillator |
| | | signal OSC_out, if no |
| | | change in temperature |
| | | signal TCODE) |
| Second Range | 0x06 | When SREF count = 6 (e.g., |
| | | after 7 pulses of oscillator |
| | | signal OSC_out, if no |
| | | change in temperature |
| | | signal TCODE) |
| . . . | . . . | . . . |
| Third Range | 0x01 | When SREF count = 1 (e.g., |
| | | after two pulses of oscillator |
| | | signal OSC_out, if no |
| | | change in temperate signal |
| | | TCODE) |
| Fourth Range (higher | 0x00 | When SREF count = 0 (after |
| temperature) | | each pulse of oscillator |
| | | signal OSC_out) |

While first, second, third, and fourth temperature ranges are illustrated in Table 1, any number of temperature ranges and corresponding temperature signals TCODE can be used. In various implementations, refresh rates may be controlled according to a refresh rate curve, such that a refresh interval decreases exponentially or substantially exponentially as temperature of the memory device increases.

The refresh control circuit 500 includes a self-refresh counter comparator 540 that receives the temperature signal TCODE from the temperature sensor 510, the self-refresh count signal SREF count from the self-refresh counter 530, and the oscillator signal OSC_out from the refresh oscillator 520. The self-refresh counter comparator 540 compares the temperature signal TCODE to the self-refresh count signal SREF count and generates a self-refresh signal SREFP to cause performance of a self-refresh operation when the self-refresh count signal SREF count matches the value specified by the temperature signal TCODE. For example, when temperature signal TCODE=0x00, SREFP is generated when self-refresh count signal SREF count=0 (i.e., every 1 pulse of OSC_out); when temperature signal TCODE=0x01, SREFP is generated when self-refresh count signal SREF count=2 (e.g., every 2 pulses of OSC_out, if there is no change in TCODE); when temperature signal TCODE=0x02, SREFP is generated when self-refresh count signal SREF count=3 (e.g., every 3 pulses of OSC_out, if there is no change in TCODE); and so forth. The self-refresh counter comparator 540 generates a reset signal RESET and provides the reset signal RESET to the self-refresh counter 530 when the self-refresh signal SREFP is generated, and the reset signal RESET causes the self-refresh counter 530 to reset the count to zero. Additionally, the reset signal RESET is generated when there is a change in the temperature signal TCODE, which also causes the self-refresh counter 530 to reset the count to zero.

An active pulse generator 550 receives the self-refresh signal SREFP and receives and processes various other active signals, such as activation command signals ACT, auto-refresh command signals AREF, self-refresh command signals SREF, and so forth. The active pulse generator 550 processes the self-refresh signal SREFP and/or the other active signals to generate a pulse signal Active Pulse to cause performance of a refresh operation.

A Bank Active component 560 receives the pulse signal Active Pulse and related precharge information, and the Bank Active component 560 generates a bank signal Bank ACT/Pre, which is provided to one or more banks in the memory device to cause performance of a refresh operation. Since the refresh operation may not be paired to a corresponding precharge command, a refresh timer 570 (e.g., a delay circuit) may generate a precharge signal Precharge Pulse to specify timing of performance of the refresh operation by the one or more banks in the memory device.

Example components of the refresh control circuit 500 are shown by way of illustration. More or fewer components may be included while maintaining a similar functionality, and various components may be combined.

FIG. 6 is a timing diagram 600 illustrating self-refresh operations performed by a memory device. For example, the self-refresh operations may be performed by the memory device 100 of FIG. 1 using a refresh control circuit, such as the refresh control circuit 116 of FIG. 1 and/or the refresh control circuit 500 of FIG. 5.

The refresh control circuit receives a self-refresh activation signal SREF_ON, which causes the memory device to enter a self-refresh mode. The self-refresh activation signal SREF_ON may be received from a command decoder (e.g., 106 of FIG. 1) of the memory device responsive to a self-refresh command generated by a controller (e.g., 140 of FIG. 1). As described herein, the self-refresh activation signal SREF_ON may also be received by a switch, and the self-refresh activation signal SREF_ON may activate the switch during at least a portion of the self-refresh mode to provide a conductive path between two or more conductive lines receiving respective voltages.

During the self-refresh mode, a self-refresh counter comparator (e.g., 540 of FIG. 5) generates a self-refresh signal SREFP to cause performance of self-refresh operations at intervals based on a temperature signal CODE received from a temperature sensor (e.g., 510 of FIGS. 5 and/or 139 of FIG. 1) that detects a temperature of the memory device and a self-refresh count signal SREF count generated by a self-refresh counter (e.g., 530 of FIG. 5). The intervals for the self-refresh operations are determined using an oscillator signal OSC_out generated by a refresh oscillator (e.g., 520 of FIG. 1). The oscillator signal OSC_out may be generated at regular intervals throughout the self-refresh mode, such as every 0.5 microseconds.

When the temperature signal TCODE=0x00, indicating a high temperature of the memory device, the self-refresh counter comparator compares the self-refresh count signal SREF count to the value indicated by the temperature signal TCODE and generates the self-refresh signal SREFP when SREF count=0. In other words, the self-refresh signal SREFP is generated with every pulse of the oscillator signal OSC_out. The count indicated by the self-refresh count signal SREF count is reset after generation of each self-refresh signal SREFP. Accordingly, self-refresh operations are performed by the memory device at each of times t₁ through t₁₀.

At time t₁₀, a value of the temperature signal TCODE changes such that TCODE=0x03, indicating a lower temperature of the memory device, as compared to TCODE=0x00.

When the temperature signal TCODE=0x03, the self-refresh counter comparator compares the self-refresh count signal SREF count to the value indicated by the temperature signal TCODE and generates the self-refresh signal SREFP when SREF count=3. For example, the self-refresh signal SREFP is generated after four pulses of the oscillator signal OSC_out when there is no change in the temperature signal TCODE. The count indicated by the self-refresh count signal SREF count is reset after generation of each self-refresh signal SREFP. Accordingly, self-refresh operations are performed by the memory device at each of times t₁₁, t₁₂, and t₁₃.

At time t₁₄, a value of the temperature signal TCODE changes such that TCODE=0x01, indicating a higher temperature of the memory device, as compared to TCODE=0x03, but a lower temperature of the memory device, as compared to TCODE=0x00. Responsive to the changed temperature signal TCODE, the count indicated by the self-refresh count signal SREF count is reset.

When the temperature signal TCODE=0x01, the self-refresh counter comparator compares the self-refresh count signal SREF count to the value indicated by the temperature signal TCODE and generates the self-refresh signal SREFP when SREF count=1. For example, the self-refresh signal SREFP is generated after two pulses of the oscillator signal OSC_out when there is no change in the temperature signal TCODE. The count indicated by the self-refresh count signal SREF count is reset after generation of each self-refresh signal SREFP. Accordingly, self-refresh operations are performed by the memory device at each of times t₁₅ and t₁₆.

At time t₁₇, a value of the temperature signal TCODE changes such that TCODE=0x06, indicating a lower temperature of the memory device, as compared to TCODE=0x00, 0x01, or 0x03. Responsive to the changed temperature signal TCODE, the count indicated by the self-refresh count signal SREF count is reset.

When the temperature signal TCODE=0x06, the self-refresh counter comparator compares the self-refresh count signal SREF count to the value indicated by the temperature signal TCODE and generates the self-refresh signal SREFP when SREF count=6. For example, the self-refresh signal SREFP is generated after seven pulses of the oscillator signal OSC_out when there is no change in the temperature signal TCODE. The count indicated by the self-refresh count signal SREF count is reset after generation of each self-refresh signal SREFP. Accordingly, a self-refresh operation is performed by the memory device at time t₁₈.

The memory device will continue performing self-refresh operations according to intervals based on the temperature signal TCODE until the memory device exits the self-refresh mode—that is, until the self-refresh activation signal SREF_ON is deactivated.

As used herein, an activation of a signal may refer to any portion of a signal waveform that a circuit responds to. For example, if a circuit responds to a rising edge, then a signal switching from a low level to a high level may be an activation. One example type of activation is a pulse, where a signal switches from a low level to a high level for a period of time, and then back to the low level. This may trigger circuits which respond to rising edges, falling edges, and/or signals being at a high logical level. One of skill in the art should understand that although embodiments may be described with respect to a particular type of activation used by a particular circuit (e.g., active high), other embodiments may use other types of activation (e.g., active low).

Of course, it is to be appreciated that any one of the examples, embodiments or processes described herein may be combined with one or more other examples, embodiments and/or processes or be separated and/or performed amongst separate devices or device portions in accordance with the present systems, devices, and methods.

Finally, the above discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a memory configured to:
receive, at a first conductive line, a first voltage provided by a power management circuit and further receive, at a second conductive line, a second voltage provided by the power management circuit;
enter a self-refresh mode responsive to a self-refresh entry command; and
conductively couple the first conductive line and the second conductive line responsive to the self-refresh entry command.

2. The apparatus of claim 1, wherein the first voltage is VDD and the second voltage is VDDQ.

3. The apparatus of claim 1, wherein the memory is configured to:
exit the self-refresh mode responsive to a self-refresh exit command; and
conductively decouple the first conductive line and the second conductive line responsive to the self-refresh exit command.

4. The apparatus of claim 3, wherein the self-refresh exit command comprises a sequence including a chip select (CS) signal at a high logic level and a plurality of no-operation (NOP) commands.

5. The apparatus of claim 1, further comprising:
a controller configured to provide the self-refresh entry command.

6. The apparatus of claim 1, wherein the power management circuit comprises a power management integrated circuit (PMIC) separate from the memory.

7. The apparatus of claim 1, wherein the memory further comprises a temperature sensor and a refresh control circuit, and wherein the refresh control circuit is configured to adjust a refresh interval based on an output of the temperature sensor.

8. An apparatus comprising:
a power source configured to provide a plurality of voltages via a plurality of power rails; and
a memory configured to receive the plurality of voltages at a plurality of conductive lines coupled to respective power rails of the plurality of power rails, wherein the memory is configured to conductively couple a first conductive line of the plurality of conductive lines and a second conductive line of the plurality of conductive lines when the memory is in a self-refresh mode.

9. The apparatus of claim 8, wherein the memory is configured to conductively decouple the first conductive line of the plurality of conductive lines and the second conductive line of the plurality of conductive lines when the memory exits the self-refresh mode.

10. The apparatus of claim 8, wherein the first conductive line is configured to receive a first voltage of the plurality of voltages and the second conductive line is configured to receive a second voltage of the plurality of voltages.

11. The apparatus of claim 10, wherein the first voltage and the second voltage are equal.

12. The apparatus of claim 10, wherein the first voltage is VDD and the second voltage is VDDQ.

13. The apparatus of claim 8, wherein the power source comprises a power management integrated circuit (PMIC).

14. A system comprising:
a command/address (CA) bus;
a memory controller configured to provide a self-refresh entry command via the CA bus;
a power management circuit configured to provide a first voltage via a first rail and to provide a second voltage via a second rail; and
a memory configured to enter a self-refresh mode responsive to receiving the self-refresh entry command via the CA bus and to conductively couple a first conductive line and a second conductive line when the memory is in the self-refresh mode, the first conductive line coupled to the first rail and the second conductive line coupled to the second rail.

15. The system of claim 14, wherein the first voltage is VDD and the second voltage is VDDQ.

16. The system of claim 14, wherein the memory comprises a refresh control circuit configured to cause performance of at least one self-refresh operation when the memory is in the self-refresh mode.

17. The system of claim 16, wherein the memory comprises a temperature sensor, and wherein the refresh control circuit is configured to adjust a refresh interval based on an output of the temperature sensor.

18. The system of claim 14, wherein the memory is configured to conductively decouple the first conductive line and the second conductive line when the memory exits the self-refresh mode.

19. The system of claim 14, wherein the memory is configured to exit the self-refresh mode responsive to receiving a sequence including a chip select (CS) signal at a high logic level and a plurality of no-operation (NOP) commands.

20. A method comprising:
receiving, at a first conductive line of a memory, a first voltage;
receiving, at a second conductive line of the memory, a second voltage;
detecting a self-refresh entry command;
entering, by the memory, a self-refresh mode responsive to the self-refresh entry command; and
conductively coupling the first conductive line and the second conductive line when the memory is in the self-refresh mode.

21. The method of claim 20, further comprising:
exiting, by the memory, the self-refresh mode; and
conductively decoupling the first conductive line and the second conductive line when the memory exits the self-refresh mode.

22. The method of claim 20, wherein the first voltage is VDD and the second voltage is VDDQ.

23. The method of claim 20, wherein the first conductive line receives the first voltage from a first rail of a power management circuit and the second conductive line receives the second voltage from a second rail of the power management circuit.

24. The method of claim 20, wherein the first voltage and the second voltage are equal.

25. The method of claim 20, wherein the first voltage and the second voltage are provided by a power management integrated circuit (PMIC).

26. The method of claim 20, wherein the first conductive line and the second conductive line are conductively coupled during a portion of the self-refresh mode.

27. The method of claim 20, wherein conductively coupling the first conductive line and the second conductive line comprises activating a switch configured to provide a conductive path between the first and second conductive lines when activated.
